(19) United States
(12) Patent Application Publication
(10) Pub. No.: US 2014/0349889 A1
(43) Pub. Date: Nov. 27, 2014

(54) FORMATION OF A SUPRA-MONOLAYER NANOPATTERN AND ITS USES

(71) Applicant: Wayne State University, Detroit, MI (US)

(72) Inventors: Guangzhao Mao, Northville, MI (US); Daniel J. Sobczynski, Saint Clair Shores, MI (US); Sunxi Wang, Detroit, MI (US); Juxhin Xhahysa, Macomb, MI (US); Pedram Jahanian, Hamtramck, MI (US)

(73) Assignee: WAYNE STATE UNIVERSITY, Detroit, MI (US)

(21) Appl. No.: 14/364,589

(22) PCT Filed: Dec. 11, 2012
(86) PCT No.: PCT/US12/68905

§ 371 Date: Jun. 11, 2014

Related U.S. Application Data
(60) Provisional application No. 61/569,478, filed on Dec. 12, 2011.

(51) Int. Cl. B01J 19/00; C23C 16/04

(52) U.S. Cl. CPC B01J 19/0046; C23C 16/04; B01J 2219/00331; B01J 2219/00313
USPC 506/23; 506/37; 427/197

(57) ABSTRACT

The present disclosure discloses a method to prepare a supra-monolayer nanopattern and its uses.

This application claims priority to U.S. Provisional Patent Application No. 61/569,478, filed Dec. 12, 2011, the entirety of which is hereby incorporated by reference.

### FIELD

The present disclosure relates to a method to prepare a supra-monolayer nanopattern and its uses. More specifically, the present disclosure relates to a particle lithography method to prepare supra-monolayer nanopatterns.

### BACKGROUND

Self-assembled monolayers (SAMs) of organosilanes including n-octadecyltrichlorosilane (OTS) on silicon wafer substrates have been known. The present disclosure describes the combination of the OTS SAM and particle lithography technologies that has yielded a simple yet reliable method to manufacture nanopatterns on silicon substrates.

### BRIEF SUMMARY

In one aspect, a method comprises disposing a plurality of microparticles onto a silicon substrate, and chemical vapor depositing a silane to the silicon substrate with the plurality of microparticles. The method also comprises allowing the silane to undergo both a bulk crosslinking reaction and a crosslinking reaction on the surface of the silicon substrate to form a nanopattern. The nanopattern comprises the plurality of microparticles and the crosslinked silane between the plurality of microparticles. The height of the crosslinked silane is greater than the height of a monolayer of the silane.

In another aspect, a device comprises a silicon substrate. The device also comprises a plurality of crosslinked silane features disposed on the silicon substrate and interfacial areas on the silicon substrate between the crosslinked silane features. The interfacial areas are part of the surface of the silicon substrate. The individual interfacial areas are surrounded by respective individual crosslinked silane features. The height of the crosslinked silane is in the nanometer range and greater than the height of a monolayer of the silane.

In yet another aspect, a method comprises providing a device and adding a material to at least one of the interfacial areas on the device. The device comprises a silicon substrate. The device also comprises a plurality of crosslinked silane features disposed on the silicon substrate and interfacial areas on the silicon substrate between the crosslinked silane features. The interfacial areas are part of the surface of the silicon substrate. The individual interfacial areas are surrounded by respective individual crosslinked silane features. The height of the crosslinked silane is in the nanometer range and greater than the height of a monolayer of the silane.

### BRIEF DESCRIPTION OF THE FIGURES

FIG. 1 illustrates SEM and AFM images of PS900 (a) and (c) and PS300 (b) and (d) on oxidized silicon wafer. The white bar in every image represents 1 μm. z-range=300 nm in (c) and (d).

FIG. 2 illustrates AFM height images and corresponding height profile for 90 min CVD of OTS nanoarray using a 900 nm particle template. Nanoarrays in (a) 5.2 L and (b) 0.13 L reaction vessels. z-ranges for (a) and (b) are 30 and 60 nm, respectively.

FIG. 3 illustrates contact angle and ring height dependence on the OTS reaction time on PS900 template. In the left figure, the dots with minute units represent OTS fraction while the other dots represent contact angle.

FIG. 4 illustrates AFM height image of OTS-covered silicon wafer covered by OTS nanorings (720 min case for PS900). z-range=60 nm.

FIG. 5 illustrates plot of ring height (made on 900 nm PS template) dependence on relative humidity in 5.2 and 0.13 L reactor, respectively.

FIG. 6 illustrates AFM height images and section analysis of single OTS nano-ring on (a) PS900 and (b) PS300. z-range=60 nm.

FIG. 7 illustrates AFM images of 40 μL of docosane's chloroform solution dip coating, then melting and quenching on 900 nm nanoring substrate. (a) 0.7 mM, and (b) 3.5 mM. z-range=60 nm.

FIG. 8 illustrates AFM height images and sectional analysis of aspirin deposition on the surface of (a) PS900 and (b) PS300 substrates. FIGS. 8(c) and (d) are docosane and clarithromycin crystallization (DE as the solvent) on PS900 substrate. The z-range for (b) is 40 nm, while others are 60 nm.

FIG. 9 illustrates AFM height images of 40 μL aspirin/DE (a) 1, (b) 0.3, and (c) 0.1 mM dip coating on PS300 substrate (z-range=20 nm) and (d) 1, (e) 0.3, and (f) 0.1 mM dip coating on PS900 substrate (z-range=60 nm).

FIG. 10 illustrates the relationship between deposited aspirin volume in a single flask (average from 50-100 samples) and the concentration (aspirin/DE) used for 40 μL dip coating on (left) PS300 and (right) PS900 substrates.

FIG. 11 illustrates the FT-IR spectrum showing that aspirin nanodots in OTS nanorings are more alike as bulk aspirin crystals rather than amorphous aspirin dissolved in ethanol. The y-axis has been offset for clarification.

### DETAILED DESCRIPTION

OTS SAM deposition from the vapor phase, i.e., the chemical vapor deposition (CVD), is often preferred over the liquid phase because the CVD deposition produces smoother OTS monolayers devoid of excessive molecular aggregates. The precise control of the CVD is however complicated by the role of water in the crosslinking reaction of the OTS. Trace water is necessary for OTS reaction with the hydroxylated silicon wafer substrate. Excessive water, however, causes self-condensation of the OTS molecules that results in random molecular aggregate deposition on the substrate. The present disclosure discloses the competitive nature of the surface reaction vs. self-condensation of the OTS molecules on oxidized silicon substrates covered by the lithographical pattern of colloidal crystals of the polystyrene microparticles with 300 and 900 nm in diameter. CVD condition that favors the self-condensation reaction of the OTS in the interstitial space of the colloidal crystal has been found, which results in the OTS supra-monolayer nanoring pattern with a typical thickness of 14 nm exceeding the OTS monolayer thickness of 2.6 nm.

According to one embodiment of the present disclosure, the supra-monolayer patterns of OTS formed by polystyrene particle lithography on silicon wafers are used as “flasks” to nucleate nanoparticles of small crystalline molecules including n-docosane, 2-acetoxybenzoic acid (i.e., aspirin), and (3R,4S,5S,6R,7R,9R,11S,12R,13S,14S)-6-{[(2S,3R,4S,6R)-4-(dimethylamino)-3-hydroxy-6-methyloxan-2-yl]oxy}-14-ethyl-12,13-dihydroxy-4-{[(2R,4S,5S,6S)-5-hydroxy-4-methoxy-4,6-dimethyloxan-2-yl]oxy}-7-methoxy-3,5,7,9,11,13-hexamethyl-1-oxacyclotetradecane-2,10-dione (i.e., clarithromycin). Docosane has been chosen because it belongs to the n-alkane homologous series with well understood chain length dependent crystallization behavior. In addition to evaporative crystallization from the solution phase, docosane is chosen because it can be re-crystallized from the melt phase at 43° C., slightly above the room temperature. 2-acetoxybenzoic acid and clarithromycin are active pharmaceutical ingredients (APIs) that are crystalline in nature. Crystallization of API sat the nanoscale is relevant to drug formulation to improve bioavailability. The supra-monolayer OTS nanopattern has been found to be an effective template for nanoparticle array deposition of all three chemicals with uniform particle size and spatial distribution as dictated by the OTS pattern size. The particle size can be further reduced by solution concentration. The particle lithography method disclosed herein overcomes the pattern thickness limit of the self-assembled monolayer. The present disclosure also describes the potential use of the supra-monolayer nanopattern for high-throughput crystallization trials and manufacture of monodisperse organic/drug nanoparticles. The solution-based particle array formation method can be scaled up for nanomanfacture of small-molecule nanoparticles of drugs, dyes, and semiconductors.

The supra-monolayer OTS nanopattern has been found to be an effective template for nanoparticle array deposition of all three chemicals with uniform particle size and spatial distribution as dictated by the OTS pattern size. The particle size can be further reduced by solution concentration.

According to another embodiment of the present disclosure, referring to Scheme 1, microparticles or nanoparticles, such as monodisperse polystyrene particles, are allowed to be deposited to a substrate, such as a silicon wafer substrate, for example by colloidal crystallization (Step 1). A silane, such as OTS, is then deposited to the substrate with the particles in a chemical vapor deposition process (Step 1). By adjusting the conditions for the chemical vapor deposition process, surprisingly, a supra-monolayer nanopattern with thickness greater than that of an OTS SAM is formed, which is presumably due to bulk crosslinking reaction of OTS under these conditions. In contrast, during OTS SAM fabrication, surface crosslinking reaction OTS controls. The thickness of the supra-monolayer nanopattern can be tuned by moisture during the chemical vapor deposition process. The supra-monolayer nanopattern is solvent stable and an inert structure.

The nanoparticles on the supra-monolayer nanopattern can be removed, such as by a mechanic means. In one example, the particles are removed by pressing a poly(dimethylsiloxane) (PDMS) stamp onto the nanopattern and lifting the particles from the silicon wafer to the PDMS stamp to form the resultant nanoflasks (Step 2). The size and shape of the microparticles/nanoparticles can be varied to make nanoflasks of different sizes and shapes. For example, microparticles with different shapes (e.g., micro-rods instead of micro-spheres) can be used to make nanoflasks of different shapes. In one example, the nanopattern assumes a ring shape (“nanoring”). A variety of silanes can be used to make different wall materials for the nanoflasks.

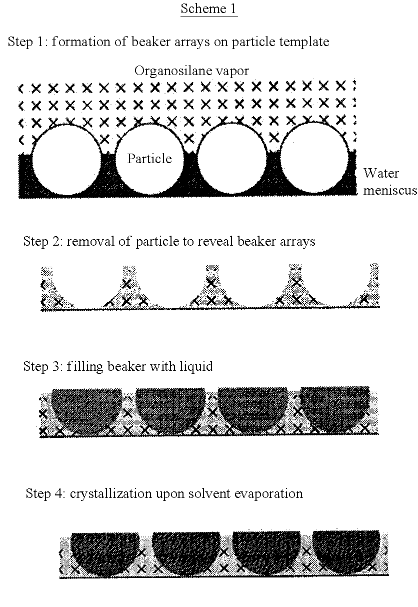

The nanoflasks/nanorings can be hydrophobic or hydrophilic. For example, the OTS nanoflasks as described in detail in the examples of the present disclosure are hydrophobic. There are other chemicals that can be used to make hydrophilic nanoflasks. For example, aminosilanes, such as 4-aminobutyldimethylmethoxysilane (ABS), together with OTS, are known to hydrophilic self-assembled monolayers. See, for example, Wu et al., Stepwise Adsorption of A Long Trichlorosilane And A Short Aminosilane, Colloids and Surfaces A: Physicochemical and Engineering Aspects, 162 (1999), pp. 203-213, the entirety of which is hereby incorporated by reference. The above OTS/ABS approach can be modified using the methods as described in the present disclosure to make hydrophilic nanorings.

There are many applications for the nanoflasks according to the present disclosure. The nanoflasks can be filled with liquids, small molecules, nanoparticle quantum dots, biomolecules, etc. For example, the nanoflasks/nanorings can be used in nanoparticle synthesis. For example, gold nanoparticles, such as oleylamide-capped gold nanoparticles (OA-AuNPs), can be prepared by known methods. See, for example, Want et al., Formation of Carboxylic Acid Nanorods on Oleylamide-Capped Au Nanoparticles, J. Phys. Chem. C, 2012, 116, pp. 5492-5498, the entirety of which is hereby incorporated by reference. Such synthesis can be conducted in the nano-rings to further control size and particle distribution.

The nano-rings can also be used in high-throughput crystallization/re-crystallization. The devices and methods of the present disclosure allow fast, inexpensive protein and crystallization/re-crystallization techniques. The crystallization/re-crystallization methods according to the present disclosure may be applied to various drugs, materials, small molecules, macromolecules, colloidal and nanoparticles, or any of their combinations. Current crystallization/re-crystallization screening technologies generally determine the ideal conditions for protein crystallization on a milligram scale.

A significant problem involving current crystallization/re-crystallization approaches is determining the conditions for forming crystals with optimal diffractive properties. For example, screening for protein crystallization/re-crystallization can involve varying a number of parameters, such as concentrations of precipitation agent, buffers, salts, and other chemical additives; the volume of crystallization trial; ratio of target solution to crystallization solution; target concentration; cocrystallization of the target with a secondary small or macromolecule; hydration; incubation time; temperature; pressure; contact surfaces; modifications to target molecules; and gravity etc. Screening using the nanoflasks described in this disclosure would provide a method that requires a minimal amount of the crystallization targets to evaluate a variety of crystallization/re-crystallization conditions.

The method according to one embodiment of the present disclosure offers a simple and inexpensive way to produce nanopattern arrays with adjustable height (inner volume), and thus enables its use as nanoflasks (or nanobeakers) with adjustable volume. For example, when the nanoflask arrays are used as a disposable plate for crystallization screening that allows fine tuning of each droplet volume, a 1×1 cm² silicon wafer substrate made with 900 nm (diameter) microparticle template contains approximately 100 million individual nanoflasks. This means that 100 million trials can be conducted at one time on one silicon plate of 1 cm² in size. The nanoflasks according to one embodiment of the disclosure provide inexpensive test plates for drug loading, precipitation, and crystallization, and also allow high-throughput chemical reaction tests with minimal amount of liquid.

According to yet another embodiment of the present disclosure, a method comprises disposing a plurality of microparticles onto a silicon substrate, and chemical vapor depositing a silane to the silicon substrate with the plurality of microparticles. The method also comprises allowing the silane to undergo both a bulk crosslinking reaction and a crosslinking reaction on the surface of the silicon substrate to form a nanopattern. The nanopattern comprises the plurality of microparticles and the crosslinked silane between the plurality of microparticles. The height of the crosslinked silane is greater than the height of a monolayer of the silane.

Preferably, the method further comprises removing the plurality of microparticles from the nanopattern so that the remaining crosslinked silane on the silicon substrate forms a microcontainer. The microparticles can be removed by a mechanic means, such as a tape, a PDMS stamp etc.

Preferably, the microparticles disposed on the silicon substrate undergo colloidal crystallization on the silicon substrate before the chemical vapor deposition of the silane. The silicon substrate is preferably a silicon wafer. Preferably, the size of the microparticles is in the nanometer or micrometer range. Preferably, the microparticles are polystyrene particles or gold particles. Preferably, the silane is n-octadecyltrichlorosilane or an aminosilane.

The height of the crosslinked silane is preferably at least twice, or three times, or four times, or five times, or six times, or seven times, or eight times, or nine times, or ten times, or eleven times, or twelve times, or thirteen times, or fourteen times, or fifteen times, or sixteen times, or seventeen times, or eighteen times, or nineteen times, or twenty times, or thirty times greater than the height of a monolayer of the silane.

Preferably, the height of the crosslinked silane is about 3 nm, about 4 nm, about 5 nm, about 6 nm, about 7 nm, about 8 nm, about 9 nm, about 10 nm, about 11 nm, about 12 nm, about 13 nm, about 14 nm, about 15 nm, about 16 nm, about 17 nm, about 18 nm, about 19 nm, about 20 nm, about 21 nm, about 22 nm, about 23 nm, about 24 nm, about 25 nm, about 26 nm, about 27 nm, about 28 nm, about 29 nm, about 30 nm, about 31 nm, about 32 nm, about 33 nm, about 34 nm, about 35 nm, about 36 nm, about 37 nm, about 38 nm, about 39 nm, about 40 nm, about 41 nm, about 42 nm, about 43 nm, about 44 nm, about 45 nm, about 46 nm, about 47 nm, about 48 nm, about 49 nm, about 50 nm, about 60 nm, about 70 nm, about 80 nm, about 90 nm, or about 100 nm. More preferably, the height of the crosslinked silane is between about 14 nm and about 22 nm.

According to still another embodiment of the present disclosure, a device comprises a silicon substrate. The device also comprises a plurality of crosslinked silane features disposed on the silicon substrate and interfacial areas on the silicon substrate between the crosslinked silane features. The interfacial areas are part of the surface of the silicon substrate. The individual interfacial areas are surrounded by respective individual crosslinked silane features. The height of the crosslinked silane is in the nanometer range and greater than the height of a monolayer of the silane.

Preferably, the size of the interfacial areas is in the nanometer or micrometer range. Preferably, the crosslinked silane is n-octadecyltrichlorosilane or an aminosilane.

The height of the crosslinked silane is preferably at least twice, or three times, or four times, or five times, or six times, or seven times, or eight times, or nine times, or ten times, or eleven times, or twelve times, or thirteen times, or fourteen times, or fifteen times, or sixteen times, or seventeen times, or eighteen times, or nineteen times, or twenty times, or thirty times greater than the height of a monolayer of the silane.

Preferably, the height of the crosslinked silane is about 3 nm, about 4 nm, about 5 nm, about 6 nm, about 7 nm, about 8 nm, about 9 nm, about 10 nm, about 11 nm, about 12 nm, about 13 nm, about 14 nm, about 15 nm, about 16 nm, about 17 nm, about 18 nm, about 19 nm, about 20 nm, about 21 nm, about 22 nm, about 23 nm, about 24 nm, about 25 nm, about 26 nm, about 27 nm, about 28 nm, about 29 nm, about 30 nm, about 31 nm, about 32 nm, about 33 nm, about 34 nm, about 35 nm, about 36 nm, about 37 nm, about 38 nm, about 39 nm, about 40 nm, about 41 nm, about 42 nm, about 43 nm, about 44 nm, about 45 nm, about 46 nm, about 47 nm, about 48 nm, about 49 nm, about 50 nm, about 60 nm, about 70 nm, about 80 nm, about 90 nm, or about 100 nm. More preferably, the height of the crosslinked silane is between about 14 nm and about 22 nm.

According to further another embodiment of the present disclosure, a method comprises providing a device and adding a material to at least one of the interfacial areas on the device. The device comprises a silicon substrate. The device also comprises a plurality of crosslinked silane features disposed on the silicon substrate and interfacial areas on the silicon substrate between the crosslinked silane features. The interfacial areas are part of the surface of the silicon substrate. The individual interfacial areas are surrounded by respective individual crosslinked silane features. The height of the crosslinked silane is in the nanometer range and greater than the height of a monolayer of the silane.

Preferably, the material is a liquid, a small molecule, nanoparticles, microparticles, or a biomolecule.

According to one embodiment of the present disclosure, it is provided a new process to make nanoarray patterns and a new use for high-throughput screening of crystallization conditions (for drugs, dyes and pigments, proteins, etc.), liquid solution applications, and other lab-on-the-chip applications. The formation process is a variation on “particle lithography” in which micro particles, such as polystyrene microparticles, are used as templates to make nanoring structure. However, previous “particle lithography” is based on organosilane surface chemistry. It produces rings limited to the monolayer height (thickness) by reaction of organosilane with silicon wafer substrates. Unexpectedly, the chemical vapor deposition conditions as described in the present disclosure produced nanoring patterns whose height exceeds the monolayer height.

In one example, microparticles of polystyrene 30, 300, and 900 nm are used as templates to make organosilane nanoflasks of controlled size. Approximately 100 million nanoflasks can be made on a 1 cm² silicon wafer substrate using 900 nm diameter microparticles. The nanoflask arrays are made by organosilane chemistry in the presence of trace water trapped by the microparticles. Unlike the previous method, nanoflask wall height is greater than monolayer height (˜3 nm). Presumably, bulk organosilane crosslinking reaction takes place in addition to the surface crosslinking reaction. These structures are solvent stable and can be commercialized as plates to screen loading, precipitation, and crystallization conditions of drugs, as well as a variety of lab-on-the-chip applications involving liquids.

### EXAMPLES

### Nano-Ring Pattern Formation by Particle Lithography

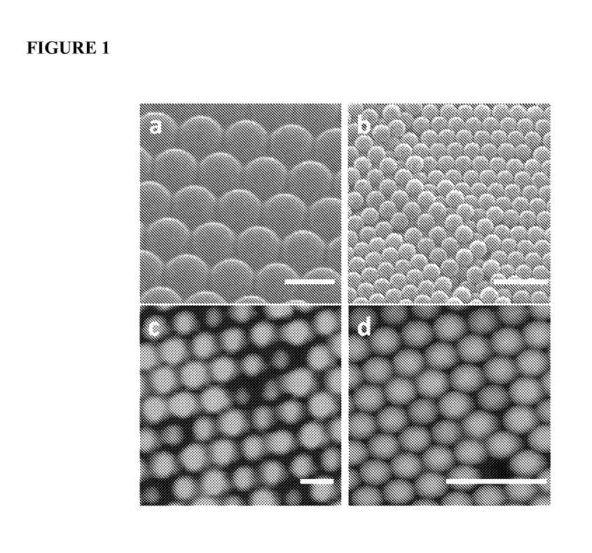

Particle lithography relies on immersion capillary force for colloidal crystallization on solid substrates. FIG. 1 shows the colloidal crystal structures formed by particle lithography on the oxidized silicon wafer by the PS900 and PS300, respectively. The average crystalline domain size is 90 μm for the PS900 and 30 μm for the PS300, respectively. It can be deduced from SEM and AFM images that more than one layer of polystyrene particles have been deposited.

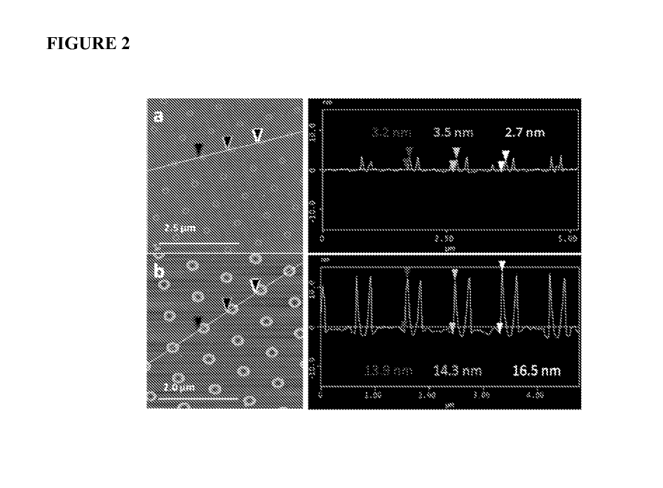

The OTS nano-ring pattern formation on PS900 and PS300 film templates is based on the hydrolyzed OTS reaction with the hydroxyl groups on the oxidized silicon wafer. Because the OTS undergoes surface reaction only in the presence of the capillary water that surrounds the polystyrene particle contact point with the substrate, the OTS nano-ring lithographic pattern is created on the polystyrene colloidal crystal film template. The thickness of the OTS lithographic pattern is generally limited to the OTS monolayer thickness of 2.6 nm, and the pattern is hydrophobic due to its methyl termination. FIG. 2a shows an AFM image and its sectional height profile of the OTS monolayer nano-ring pattern deposited by particle lithography on the oxidized silicon wafer with a ring height of 3.0±0.5 nm (N=50). Surprisingly, however, it has been observed that under certain conditions OTS lithographic patterns display film thickness higher than the monolayer thickness, which are called supra-monolayer nano-ring patterns. FIG. 2b shows an AFM image and its sectional height profile of a supra-monolayer pattern with a ring height of 14.4±2.4 nm (N=50). The reaction conditions of the supra-monolayer patterns are investigated.

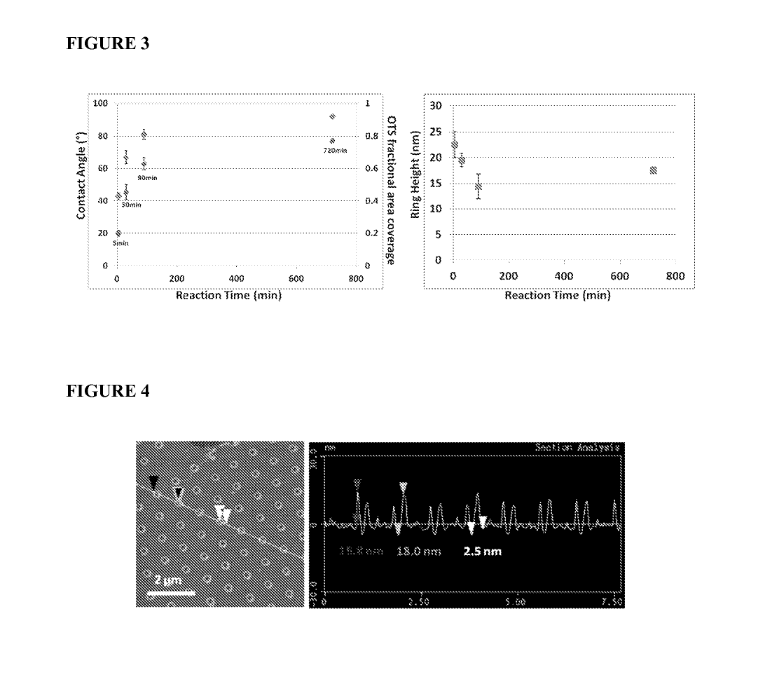

The OTS CVD on polystyrene colloidal template is studied as a function of the reaction time, relative humidity, and reactor volume. The OTS amount is fixed at 100 μL. First, the reaction time is varied from 5 to 720 minutes at a relative humidity of 5% and temperature of 24° C. in 0.13 L reactor. The OTS deposition is characterized by contact angle measurements and AFM. FIG. 3 shows the contact angle and the nano-ring height variations with various reaction times. The water contact angle increases steadily during the initial 90 minutes of reaction and reaches a maximum value of 92° at 720 minutes. The OTS fractional area coverage (ƒ), plotted also in FIG. 3a, is estimated from the contact angle value (θ) using the Cassie Equation (Eq.1):

cos θ=ƒ cos θ_{OTS}+(1−ƒ)cos θ_{S} (Eq.1).

where θ_{OTS} and θ_{S} are the contact angles of the OTS monolayer and substrate (oxidized silicon wafer), respectively. It has been assumed that θ_{OTS} and θ_{S} to be 110° and 0°, respectively, as reported in Wu et al., Stepwise Adsorption of A Long Trichlorosilane and A Short Aminosilane, Colloids and Surfaces A—Physicochemical and Engineering Aspects 2000, 162 (1-3), pp. 203-213, which is hereby incorporated by reference. The effect of surface roughness is neglected. ƒ=0.20 for θ=43° at 5 minute reaction time. ƒ can also be estimated from the AFM images.

In FIG. 2b, the ƒ value is calculated to be 0.14 using nano-rings with average outer and inner diameters of 379 and 160 nm, respectively, and 24 rings on a 4×4 μm² wafer area. However, if the coverage by the OTS disks (Scheme 2b) is considered by using the ring outer diameter as the disk diameter and same number of rings per unit area as above, the ƒ value is calculated to be 0.20. The actual shape of the nano-ring is the cone shape (Scheme 2c) with decreasing amount of OTS toward the bottom of the cone. ƒ=0.77 for θ=92° at 720 minute reaction time.

AFM images of the nano-rings at different reaction times show similar ring size therefore the contact angle increase with the reaction time is not due to changes in the OTS ring coverage. A closer examination of the nano-rings formed at 5 minutes and at 720 minutes show the difference between the two nano-ring patterns (FIG. 4). There is no height difference between the center of the ring and area outside the ring at 5 minute reaction time indicating no significant OTS deposition in the area outside the ring. At 720 minute, the area outside the ring is higher than the center of the ring by close to 2.6 nm indicating significant OTS deposition outside the ring. Therefore one can conclude that the OTS molecules are increasingly deposited in the area outside the nano-ring with increasing reaction time, which results in an overall increase in the water contact angle with the patterned surface. Scheme 1d shows the high contact angle nano-ring pattern in comparison with the low contact angle nano-ring pattern (Scheme 2c). The fractional area coverage values from contact angle and AFM are therefore consistent with each other. The increase in contact angle with time indicates that OTS is increasingly deposited outside the interstitial water space.

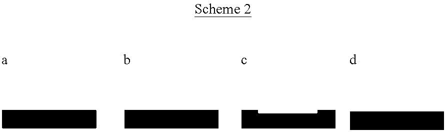

The OTS ring thickness varies between 15 and 22 nm with the maximum value obtained at the beginning of the reaction and the minimum value obtained at 90 minutes of the OTS reaction. The origin of this variation in film thickness is not clear. The OTS nano-ring patterns made at 90 minute reaction time is used for nanoparticle deposition experiments.

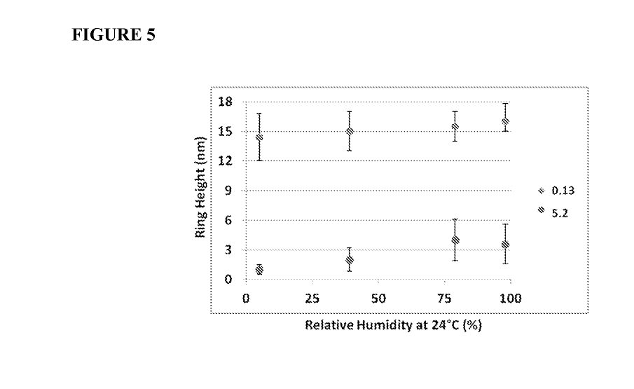

FIG. 5 plots the nano-ring height as a function of relative humidity and reactor volume at 24° C. after 90 minutes of reaction time with a fixed OTS liquid volume of 100 μL. The relative humidity is varied from 5%, 39%, 79%, to 98% by N₂ purging and using saturated salt solutions of MgCl₂, NaCl, and K₂SO₄, respectively. Glass desiccators of 0.13 and 5.2 L are used as reactors. The data show that relative humidity has a weak effect on the nano-ring pattern thickness. However, the supra-monolayer nano-ring pattern only forms when the reactor volume is sufficiently small. The nano-ring thickness is around the monolayer thickness when the larger 5.2 L dessicator is used. The small reactor volume seems necessary to maintain high vapor pressure of the OTS to undergo self-cross-linking reaction among the interstitial colloidal crystal space above the substrate. It may be possible to increase the nanopattern thickness by using even smaller reactors.

### Nano-Ring Morphology

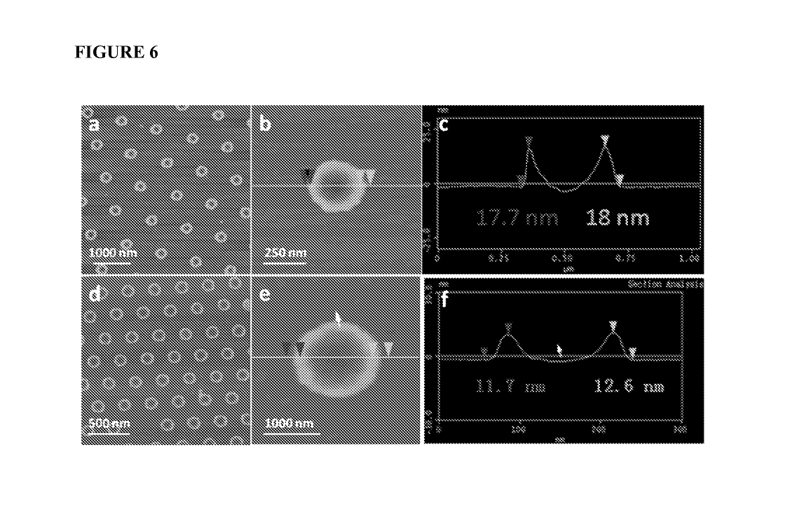

The nano-ring patterns made in 0.13 L reactor at 5% relative humidity and after 90 minute reaction time on the PS900 and PS300 templates are used for nanoparticle deposition and studied in more detail by AFM (FIG. 6) prior to their use. The PS900 template can be used to generate 1×10⁸ nano-rings per cm² while 5×10⁸ nano-rings per cm² can be generated using the PS300 template. It is expected to deposit similar numbers of nanoparticles provided that nanoparticle deposition can be regulated by the nano-ring pattern.

For PS900, the nano-ring height, outer diameter, and inner diameter are measured to be 14.4±2.4 nm, 379±46 nm, and 160±32 nm, respectively. The nano-ring has cone shape according to its sectional height profile with decreasing OTS amount toward the center of the ring. The nano-ring if used as a “flask” has an individual volume capacity of (3.0±1.5)×10⁵ nm³ or 3.0×10⁻¹⁰ nL. Similarly, the OTS nano-rings formed on the PS300 template are 10.3±2.2 nm in height, 121±25 nm in outer diameter, and 56±14 nm in inner diameter, respectively. The corresponding OTS nano-ring internal volume is (0.5±0.2)×10⁵ nm³ or 5.0×10¹¹ nL.

The supra-monolayer nano-ring patterns are stable against repeated solvent treatments. AFM and contact angle measurements have been conducted before and after immersing the patterns in organic solvents including chloroform, diethyl ether, heptane, and 1-butanol for at least 30 minutes and no evidence of pattern degradation has been found. The nano-ring pattern in 1-butanol and heptane has been imaged by AFM and no evidence of pattern swelling or degradation has been found in these solvents.

### Deposition of Nanoparticles on the Nano-Ring Pattern

The use of the nano-ring pattern to regulate the deposition and re-crystallization of small organic molecules from the liquid phase has been studied. Three hydrophobic molecules in the crystalline powder form, n-docosane, 2-(acetyloxy)benzoic acid, and clarithromycin, are used for the re-crystallization study to demonstrate the potential use of the OTS nano-arrays as containers for a wide range of organic nanoparticles.

Docosane was chosen because it belongs to the n-alkane homologous series whose crystallization behavior has been extensively studied. In addition to evaporative crystallization, n-docosane can be re-crystallized from its melt with a melting temperature of 43° C. In melt crystallization of n-docosane, a thin film of n-docosane was deposited on the substrate by solvent evaporation of 40 μL of 3.5 mM chloroform solution. The substrate covered by the thin film was heated above its melting temperature (90° C. was used) for 30 minutes and then placed in a freezer (−20° C.) for 30 minutes.

Aspirin and clarithromycin are active pharmaceutical ingredients that can be easily crystallized from the solution phase. To fill the nano-rings with organic molecules from the solution phase, a 40 μL droplet of the organic molecule's diethyl ether solution, the amount needed to form a thin liquid film covering a 1 cm² substrate, was placed on the OTS nano-arrays. The solution concentration was varied from 3 to 0.1 mM.

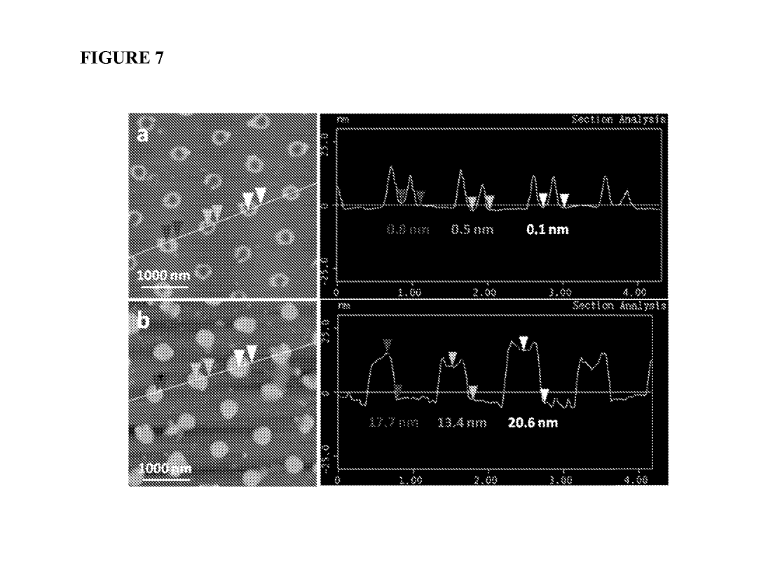

The deposited amount has been found to be a function of the solution concentration. 40 μL droplets of docosane dissolved in various solvents including ethanol, chloroform, and diethyl ether have been placed on the patterned substrates. Diethyl ether has been found to yield the smoothest film texture probably because of its high vapor pressure. Upon heating the as-deposited docosane film above its melting temperature docosane spreads uniformly on the patterned substrate to form a continuous liquid layer. The docosane liquid film was subsequently cooled quickly to −20° C. AFM imaging of the films thus formed at different docosane concentrations show little particle deposition when the solution concentration is less than 0.7 mM. Above 7 mM, the docosane layer is too thick and covers up the underlying ring pattern. At concentrations between 0.7 and 7 mM increasing amount of docosane has been deposited with increasing concentration with docosane preferentially deposited to inside the ring. Docosane depositions at 0.7, 3.5, and 7 mM have been conducted and the film structures have been imaged by AFM (FIG. 7). FIG. 7 shows the concentration, 3.5 mM, at which the amount of docosane deposited inside the ring has reached the maximum amount. The sectional height analysis shows average feature height to be 18.6±2.6 nm and average outer diameter to be 431±53 nm. The average volume of the docosane particle per nano-ring is calculated based on the AFM bearing analysis and assuming a cylindrical geometry to be 1.2×10⁶ nm³. This is 4 times the inner nano-ring volume, 3×10⁵ nm³, due to the overflow of the deposited docosane above the rim of the nano-ring. The average nano-ring height before docosane deposition is 15 nm and 17 nm after docosane filling. This shows the strong preference of docosane deposition and nucleation inside the nano-ring.

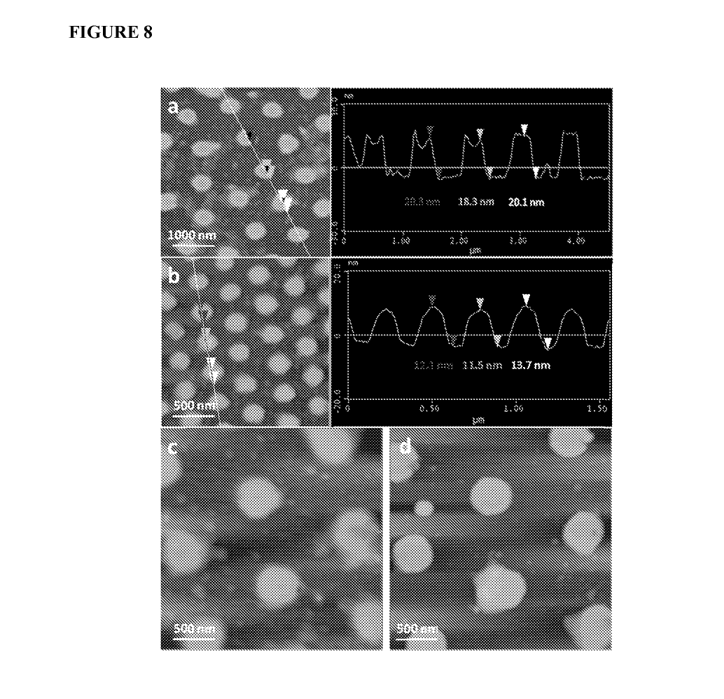

Similar concentration dependence and preferential deposition inside the nano-ring have been observed using 2-(acetyloxy)benzoic acid and clarithromycin by re-crystallization from their solution phases. For solution deposition, a 40 droplet of docosane, 2-(acetyloxy)benzoic acid, or clarithromycin of various concentrations in diethyl ether is placed on the patterned substrate and allows to dry. Maximum filling of the nano-ring has been obtained at concentrations of 0.7, 3, and 0.2 mM for docosane, 2-(acetyloxy)benzoic acid, and clarithromycin, respectively (FIG. 8). The nano-rings at the maximum filling are 3-5 nm taller than the empty ones. In FIG. 8a, the sectional height analysis shows an average height of 18.3±2.4 nm and average outer diameter of 424±50 nm. In FIG. 8b, an average height of 12.4±1.2 nm and outer diameter of 163±23 nm have been determined. FIGS. 8c and 8d show similar results as FIG. 8a. The results demonstrate the potential of the OTS nano-ring pattern for the selective deposition and nucleation of hydrophobic nanoparticles into ordered 2-D arrays.

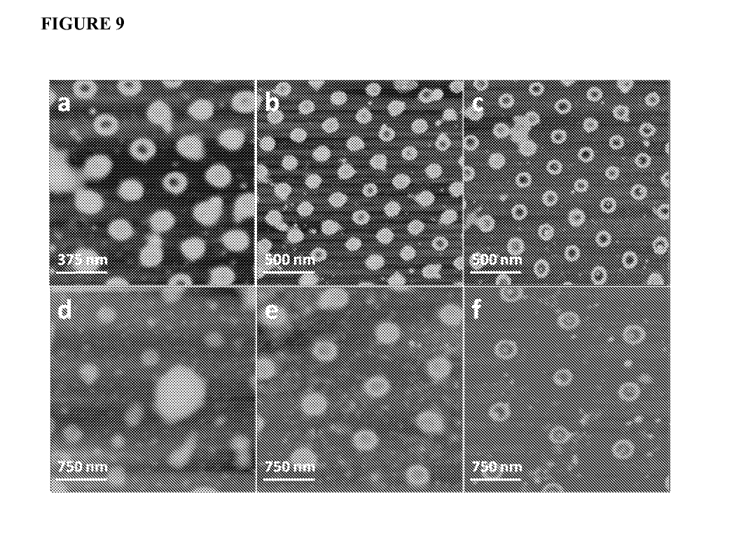

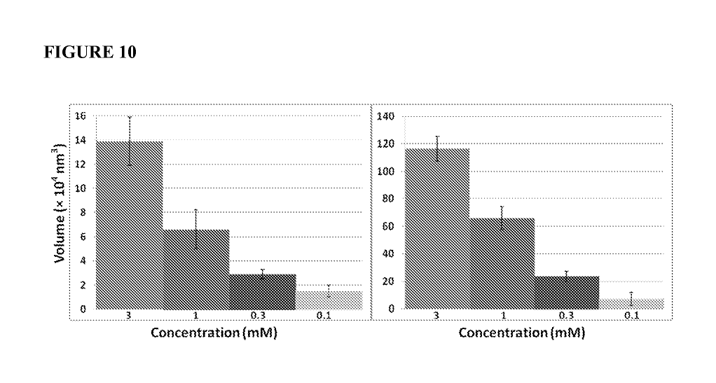

In addition, the nanoparticle size deposited in the nano-ring can be varied by solution concentration. FIG. 9 (a), (b), and (c) show 2-(acetyloxy)benzoic acid deposition on the PS300 from diethyl ether solution of decreasing concentration from 3 to 1, 0.3 and 0.1 mM, respectively. At the lowest concentration studied, 0.1 mM, nanoparticles with diameter of 30-60 nm can be found. A similar trend on the PS900 has been found (FIG. 9d-f). FIG. 10 plots the corresponding particle volume per nano-ring as a function of the solution concentration.

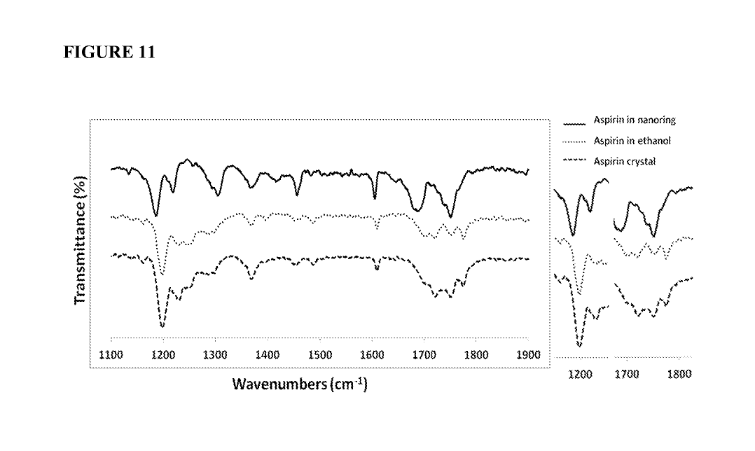

FTIR has been used to investigate the crystallinity of 2-(acetyloxy)benzoic acid nanoparticles deposited on the ring pattern. FIG. 11 shows the IR spectra of bulk 2-(acetyloxy)benzoic acid powder as purchased, aspirin dissolved in ethanol solution, and re-crystallized aspirin nanoparticles on the nano-ring pattern (sample of FIG. 10d), respectively. The FTIR spectrum of the re-crystallized nanoparticles closely resembles that of the crystalline 2-(acetyloxy)benzoic acid suggesting that the re-crystallized nanoparticles from fast evaporation of diethyl ether deposited on the nano-ring pattern are crystalline in nature.

### EXPERIMENTALS

### Materials

The following chemicals have been used as received: n-octadecyltrichlorosilane (OTS, 95%, Gelest), hydrogen peroxide (30% in water, Fisher), sulfuric acid (98% in water, Fisher), sodium chloride (99%, Fisher), magnesium chloride (>99%, Fisher), potassium sulfate (>99%, Fisher), ethanol (200 proof, Fluka), chloroform (99.9%, Fisher), diethyl ether (>99%, Alfa Aesar), 1-butanol (99.9%, Fisher), heptane (99%, Fisher), n-docosane (C₂₂H₄₆, 99%, Aldrich), 2-acetoxybenzoic acid (C₉H₈O₄, >99%, Sigma), clarithromycin (C₃₈H₆₉NO₁₃, >95%, Sigma). Deionized water from Barnstead Nanopure water purification system (resistivity 18 MΩ·cm) has been used.

One-sided polished N type silicon (111) wafers (test grade, with resistivity of 1□20 Ω·cm and thickness of 525±50 μm) have been purchased from the Wafer World. Organic residues on the silicon wafer have been removed by immersing it in 3:1 mixture of sulfuric acid and 30% hydrogen peroxide for 1 hour. The substrate has been washed with copious amounts of deionized water and dried in stream of compressed N₂.

### Particle Lithography

Monodisperse polystyrene micro-spheres with diameters of 900 nm (PS900) and 300 nm (PS300) have been used in particle lithography. Both have been purchased from the Thermo Scientific. The polystyrene particle suspension has been centrifuged for 15 min at 13,000 rpm to remove surfactants in supernatant. The solid pellet at the bottom of the centrifuge tube has been re-dispersed in deionized water to a concentration of 1 w/v %. Approximately 30 μl of the suspension has been placed on a 1×1 cm² silicon wafer substrate for 30-45 minutes in the ambient laboratory atmosphere (relative humidity 40%) to allow polystyrene to undergo colloidal crystallization. The substrate has been vacuum-dried for 30 minutes in order to remove excess water.

The OTS nano-ring pattern on the polystyrene colloidal crystal template is conducted by modifying a procedure as reported in Li et al., Elucidating the Role of Surface Hydrolysis in Preparing Organosilane Nanostructures via Particle Lithography, Nano Letters, 2008, 8(7), pp. 1916-1922; Li et al., Engineering the Spatial Selectivity of Surfaces at the Nanoscale Using Particle Lithography Combined with Vapor Deposition of Organosilanes, ACS Nano, 2009, 3(7), pp. 2023-2035; and Lusker et al, Particle Lithography with Vapor Deposition of Organosilanes: A Molecular Toolkit for Studying Confined Surface Reactions in Nanoscale Liquid Volumes, Thin Solid Films, 2011, 7(519), pp. 5223-5229, all of which are hereby incorporated by reference. The polystyrene template, that is, the oxidized silicon wafer substrate covered by polystyrene crystals, is placed in a desiccator with 100 μL OTS. The dessicator is placed in the oven at 70° C. for 90 minutes for the chemical vapor deposition of OTS with the polystyrene template. The relative humidity in the dessicator is varied by using saturated salt solutions and measured by a humidity meter (HX71-MA, Omega) immediately prior to the OTS reaction. After the reaction, the polystyrene particles are removed by sonication in a 1:1 mixture of ethanol and deionized water to reveal the OTS nano-ring pattern. The polystyrene particles can also be removed by a mechanic means, such as pressing a poly(dimethylsiloxane) (PDMS) stamp onto the template and lifting the particles from the template to the PDMS stamp.

### Deposition of Small Organic Molecules on the OTS Nano-Ring Pattern

By trial and error, it was found that approximately 40 μL droplet solution is ideal for organic nanoparticle deposition on 1 cm² OTS nano-ring pattern by evaporative re-crystallization. Lower amount results in incomplete coverage of the substrate by the solution while higher amount results in thick deposits covering up the nano-ring pattern. The droplet amount is further adjusted for each molecule at different solution concentrations. In melt re-crystallization of docosane, it is necessary to limit the amount of docosane on the substrate so that the nano-ring pattern is not completely submerged under the docosane deposit. This has been achieved by evaporative deposition of sufficiently dilute docosane solution. The substrate covered by the docosane thin film is heated above its melting temperature at 90° C. for 30 minutes. The substrate is placed immediately in a freezer at −20° C. for fast re-crystallization.

### Characterization

The particle lithography and organic nanoparticle deposition are characterized by atomic force microscopy (AFM) and field-emission scanning electron microscopy (SEM). AFM images are obtained with the J scanner (maximum scan area=125×125 μm²) (Nanoscope IIIa, VEECO). Height, amplitude, and phase images are obtained in the tapping mode in ambient air. Uncoated silicon probes (TESP, VEECO) with a factory-specified spring constant of 40 N/m, length of 125 μm, width of 40 μm, and nominal tip radius of curvature less than 10 nm are used. The scan rate used is in the range of 0.5□1 Hz depending on the scan size. Integral and proportional gains are approximately 0.4 and 0.8, respectively. All reported AFM images are height images unless otherwise specified. Height images have been plane-fit in the fast scan direction with no additional filtering operation. Images are analyzed using the Nanoscope software from Digital Instruments (Version 5.12). The various lateral and vertical sizes are measured manually using the sectional height analysis command. The nanoparticle volumes are measured by the bearing analysis command.

The nanostructures are characterized by a thermal field-emission scanning electron microscope (FESEM, JEOL JSM-7600F). A thin layer of gold (˜10 nm) is sputter coated (EffaCoater) on the sample for better image resolution. The FESEM images are obtained at a working distance of 8 nm and voltage of 15 kV.

The surface hydrophobicity is measured with an NRL contact angle goniometer (Model 100, Rame-Hart) in the laboratory atmosphere. A 10 μL water droplet is placed on the substrate and the static contact angles are measured on both sides of the droplet. Three droplets are placed at various spots on the substrate and the average readings are reported. The typical error is ±3°. In addition, the aspirin nanodots filled nano-rings were analyzed by Fourier Transfer Infrared Spectrometer (Perkin Elmer Spectrum 400) to determine aspirin's crystallinity. The crystalline structure of 2-acetoxybenzoic acid nanoparticles is analyzed by FTIR (Perkin Elmer Spectrum 400).

The present disclosure discloses OTS chemical vapor deposition conditions for particle lithography using polystyrene colloidal particles of 300 and 900 nm in diameter that yield nano-ring patterns with thickness exceeding that of the monolayer. The OTS ring thickness varies between 15 and 22 nm with the maximum value obtained at the beginning of the reaction and the minimum value obtained at 90 minutes of the OTS reaction. The patterned substrate hydrophobicity can be further tuned by OTS deposition outside the ring. The supra-monolayer nano-ring patterns are stable against repeated solvent treatments, which make them suitable for use in organic solvents. The supra-monolayer patterns silicon wafers have been used as “flasks” to nucleate nanoparticles of small crystalline molecules including n-docosane, 2-acetoxybenzoic acid (i.e., aspirin), and clarithromycin. The supra-monolayer OTS nanopattern has been found to be an effective template for nanoparticle array deposition of all three chemicals with uniform particle size and spatial distribution as dictated by the OTS ring size. The particle size can be further reduced by solution concentration. The particle lithography method described in the present disclosure overcomes the pattern thickness limit of the self-assembled monolayer. The present disclosure provides the potential use of the supra-monolayer nanopattern for high-throughput crystallization trials and manufacture of monodisperse organic/drug nanoparticles.

The novel particle lithography method of the present disclosure can be used for any purpose. For example, the disclosed method can be used to prepare nanopatterns or for nanoparticle deposition. In another example, the resultant nanopatterns can be used as nano-containers for high-throughput crystallization. This technology provides a simple and low cost approach for nanofabrication.

While the present disclosure has been described with reference to certain embodiments, other features may be included without departing from the spirit and scope of the present disclosure. It is therefore intended that the foregoing detailed description be regarded as illustrative rather than limiting, and that it be understood that it is the following claims, including all equivalents, that are intended to define the spirit and scope of this invention.

1. A method, comprising:
disposing a plurality of microparticles onto a silicon substrate;
chemical vapor depositing a silane to the silicon substrate with the plurality of microparticles; and
allowing the silane to undergo both a bulk crosslinking reaction and a crosslinking reaction on the surface of the silicon substrate to form a nanopattern, the nanopattern comprising the plurality of microparticles and the crosslinked silane between the plurality of microparticles,
wherein the height of the crosslinked silane is greater than the height of a monolayer of the silane.

2. The method of claim 1, further comprising removing the plurality of microparticles from the nanopattern, the remaining crosslinked silane on the silicon substrate forming a microcontainer.

3. The method of claim 1, wherein the microparticles undergo colloidal crystallization on the silicon substrate before the chemical vapor deposition of the silane.

4. The method of claim 1, wherein the size of the microparticles is in the nanometer or micrometer range.

5. The method of claim 1, wherein the microparticles are polystyrene particles.

6. The method of claim 1, wherein the microparticles are gold particles.

7. The method of claim 1, wherein the silane is n-octadecyltrichlorosilane.

8. The method of claim 1, wherein the silane is an aminosilane.

9. The method of claim 1, wherein the height of the crosslinked silane is twice greater than the height of a monolayer of the silane.

10. The method of claim 1, wherein the height of the crosslinked silane is three times greater than the height of a monolayer of the silane.

11. The method of claim 1, wherein the height of the crosslinked silane is between about 14 nm and about 22 nm.

12. A device, comprising:
a silicon substrate; and
a plurality of crosslinked silane features disposed on the silicon substrate and interfacial areas on the silicon substrate between the crosslinked silane features, the interfacial areas being part of the surface of the silicon substrate,
wherein the individual interfacial areas are surrounded by respective individual crosslinked silane features, and
wherein the height of the crosslinked silane is in the nanometer range and greater than the height of a monolayer of the silane.

13. The device of any of claim 12, wherein the size of the interfacial areas is in the nanometer or micrometer range.

14. The device of claim 12, wherein the crosslinked silane is n-octadecyltrichlorosilane.

15. The device of claim 12, wherein the crosslinked silane is an aminosilane.

16. The device of claim 12, wherein the height of the crosslinked silane is twice greater than the height of a monolayer of the silane.

17. The device of claim 12, wherein the height of the crosslinked silane is three times greater than the height of a monolayer of the silane.

18. The device of claim 12, wherein the height of the crosslinked silane is between about 14 nm and about 22 nm.

19. A method, comprising:
providing a device of claim 12; and
adding a material to at least one of the interfacial areas.

20. The method of claim 19, wherein the material is a liquid, a small molecule, nanoparticles, microparticles, or a biomolecule.
